(19) United States
(12) Patent Application Publication
(10) Pub. No.: US 2010/0164559 A1
(43) Pub. Date: Jul. 1, 2010

(54) POWER-ON CIRCUIT

(76) Inventor: Sung-Jin Park, Bucheon-si (KR)

Correspondence Address: SHERR & VAUGHN, PLLC, 620 HERNDON PARKWAY, SUITE 320, HERNDON, VA, 20170, US

(21) Appl. No.: 12/641,097

(22) Filed: Dec. 17, 2009

(30) Foreign Application Priority Data
Dec. 30, 2008 (KR) 10-2008-0137482

(51) Int. Cl. H03K 3/00

(52) U.S. Cl. 327/108

(57) ABSTRACT

The power-on circuit includes a first I/O voltage detector configured to detect whether or not an I/O voltage is applied and output an I/O voltage detection signal based on the detected result, a second I/O voltage detector configured to detect when the applied I/O voltage becomes a reference level value and output a cut signal based on the detected result, a core voltage detector configured to detect whether or not a core voltage is applied and output a core voltage detection signal based on the detected result, and a power-on signal generator configured to generate a power-on signal based on the I/O voltage detection signal, the cut signal and the core voltage detection signal and forcibly generate the power-on signal if the I/O voltage is stabilized later than the core voltage.

The present application claims priority under 35 U.S.C §119 to Korean Patent Application No. 10-2008-0137482 (filed on Dec. 30, 2008), which are hereby incorporated by reference in its entirety.

### BACKGROUND

A semiconductor chip may generally be subjected to a series of initialization procedures when entering a startup condition by applying an external voltage to the semiconductor chip. During startup, because the states of input/output (I/O) terminals of the chip are not known, a Retention Programmable Input Output (RPIO) scheme may be used to avoid data collision with another system connected with the chip. When an I/O voltage and a chip internal voltage (referred to hereinafter as a “core voltage”) are separately used in an RPIO scheme, there may be a need for a power-on circuit (POC) for detecting whether or not the I/O voltage is applied so as to generate a reset signal at a specific voltage and detecting the core voltage so as to stop the reset signal at a specific voltage.

As illustrated in FIG. 1, a block diagram of power-on circuit 100 includes (I/O) voltage detector 110 for outputting I/O voltage detection signal P₁ according to the application of I/O voltage DVDD, core voltage detector 120 for outputting a core voltage detection signal P_{c} according to the application of core voltage VDD, and power-on signal generator 130 for receiving I/O voltage detection signal P₁ and core voltage detection signal P_{c} and outputting power-on signal Pₒₙ.

As illustrated in FIG. 2, circuit diagram is provided illustrating power-on signal generator 200 illustrated in FIG. 1. When I/O voltage DVDD is less than a detection voltage, I/O voltage detection signal P₁ has a low potential and power-on signal Pₒₙ has a low potential. In contrast, when I/O voltage DVDD is greater than the detection voltage, I/O voltage detection signal P₁ has a high potential and power-on signal Pₒₙ has a high potential. When core voltage VDD is greater than the detection voltage, core voltage detection signal P_{c} has a high potential and power-on signal Pₒₙ has a low potential. Power-on signal generator 200 can control the power-on circuit by the core voltage having a level less than that of I/O voltage DVDD. However, if the I/O voltage is stabilized later than the core voltage, the power-on signal may not be normally generated.

### SUMMARY

Embodiments relate to a power-on circuit that generates a normal power-on signal if an I/O voltage is stabilized later than a core voltage.

In accordance with embodiments, a power-on circuit can include at least one of the following: a first Input/output (I/O) voltage detector configured to detect whether or not an I/O voltage is applied and to output an I/O voltage detection signal P₁ based on the detected result; a second I/O voltage detector configured to detect when the applied I/O voltage becomes a reference level value and to output a cut signal based on the detected result; a core voltage detector configured to detect whether or not a core voltage is applied and to output a core voltage detection signal based on the detected result; and a power-on signal generator configured to generate a power-on signal based on the I/O voltage detection signal, the cut signal and the core voltage detection signal and to forcibly generate the power-on signal if the I/O voltage is stabilized later than the core voltage.

In accordance with embodiments, the power-on circuit makes it possible to control the power-on circuit using a core voltage having a level less than that of an I/O voltage and to forcibly generate a power-on signal so as to generate a normal power-on signal if the I/O voltage is stabilized later than the core voltage.

In accordance with embodiments, a power-on circuit can include at least one of the following: a first voltage detector configured to detect whether or not an I/O voltage is applied and output an I/O voltage detection signal based on the detected result; a second voltage detector configured to detect when the applied I/O voltage becomes a reference level value and output a cut signal based on the detected result; a third voltage detector configured to detect whether or not a core voltage is applied and output a core voltage detection signal based on the detected result; and a power signal generator configured to generate a power-on signal which controls an I/O circuit of a semiconductor chip and forcibly generates the power-on signal if the I/O voltage is stabilized later than the core voltage.

### DRAWINGS

FIGS. 1 and 2 illustrate a power-on circuit and a power-on signal generator.

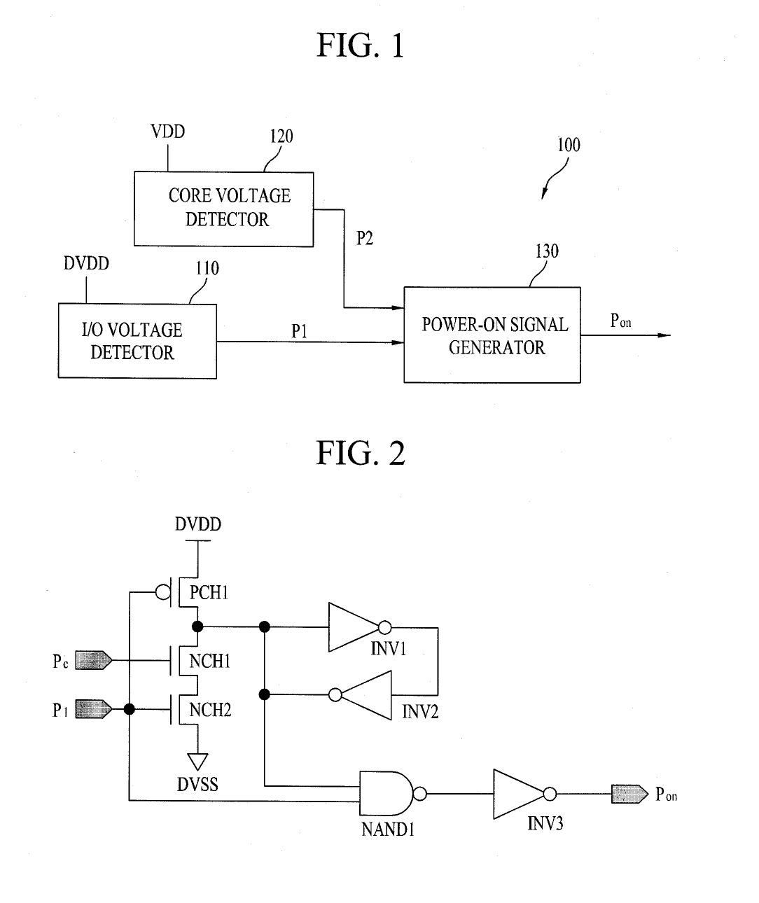

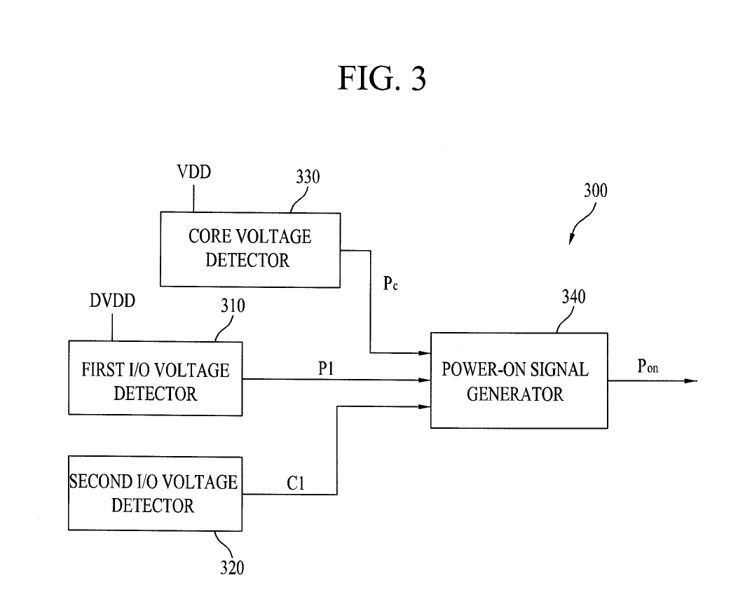

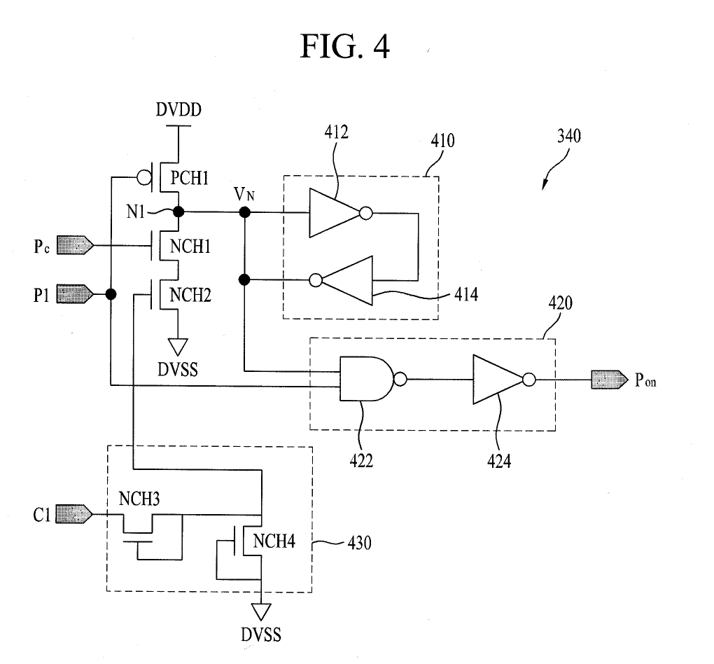

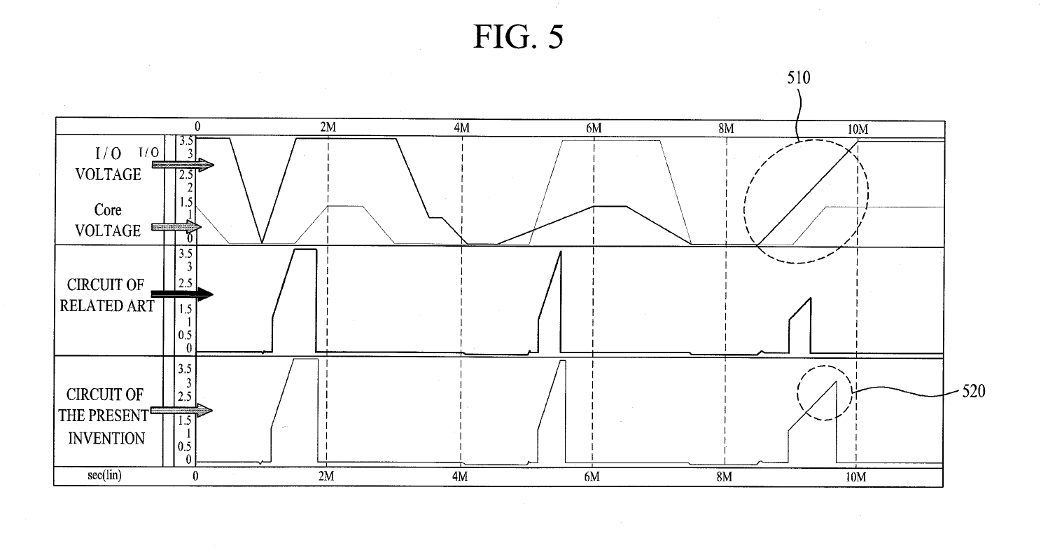

Example FIGS. 3 to 5 illustrate a power-on generation circuit, a power-on signal generator and a power-on signal output from the power-on signal generator, in accordance with embodiments.

### DESCRIPTION

Reference will now be made in detail to embodiments, examples of which are illustrated in the accompanying drawings.

Example FIG. 3 is a block diagram illustrating power-on generation circuit 300 in accordance with embodiments.

As illustrated in example FIG. 3, power-on signal generation circuit 300 includes first I/O voltage detector 310, second I/O voltage detector 320, core voltage detector 330, and power-on signal generator 340. Power-on signal generation circuit 300 generates power-on signal Pₒₙ for controlling an I/O circuit of a semiconductor chip. First I/O voltage detector 310 detects whether or not an I/O voltage is applied and outputs I/O voltage detection signal P₁ based on the detected result.

If the I/O voltage is applied and is smaller than a first reference voltage, I/O voltage detector 310 outputs an I/O voltage detection signal P₁ having a first level. Meaning, if the applied voltage is smaller than the first reference voltage, I/O voltage detector 310 determines that the I/O voltage is not applied and outputs I/O voltage detection signal P ₁ having the first level.

In contrast, if the applied voltage is larger than the first reference voltage, I/O voltage detector 310 determines that I/O voltage DVDD is applied and outputs I/O voltage detection signal P₁ having a second level. The first level may be a low voltage level and the second level may be a high voltage level. The low voltage level and the high voltage level may be determined according to chip driving characteristics.

Second I/O voltage detector 320 detects when the applied I/O voltage becomes a reference level value and outputs cut signal C₁ based on the detected result. The reference level value may be a normal state value of the I/O voltage or 80 to 99% of the normal state value. Core voltage detector 330 detects whether or not a core voltage is applied and outputs core voltage detection signal P_{c} based on the detected result.

If the core voltage is applied and is less than a second reference voltage, core voltage detector 330 outputs core voltage detection signal P_{c} having a first level. Meaning, if the applied core voltage is less than the second reference voltage, core voltage detector 330 determines that core voltage VDD is not applied and outputs core voltage detection signal P_{c} having the first level.

In contrast, if the applied core voltage is greater than the second reference voltage, core voltage detector 330 determines that core voltage VDD is applied and outputs core voltage detection signal P_{c} having the second level.

Power-on signal generator 340 generates power-on signal Pₒₙ based on I/O voltage detection signal P₁, cut signal C₁ and core voltage detection signal P_{c}.

Example FIG. 4 is a circuit diagram illustrating the configuration of power-on signal generator 340 illustrated in example FIG. 3. As illustrated in example FIG. 4, power-on signal generator 340 includes first conductive type first transistor PCH1, second conductive type first transistor NCH1, second conductive type second transistor NCH2, latch 410, logic operation unit 420 and power signal controller 430. Although the case where the first conductive type is a P type and the second conductive type is an N type is described, the first conductive type may be the N type and the second conductive type may be the P type.

First conductive type first transistor PCH1, second conductive type second transistor NCH1 and second conductive type third transistor NCH2 are sequentially connected in series between I/O voltage DVDD and ground voltage DVSS. For example, first conductive type first transistor PCH1 includes a source to which I/O voltage DVDD is applied, a drain connected to a drain of second conductive type first transistor NCH1, and a first gate to which I/O voltage detection signal P₁ is applied.

Second conductive type first transistor NCH1 includes a drain connected to the drain of first conductive type first transistor PCH1, a source connected to a drain of second conductive second transistor NCH2, and a second gate to which cut signal P_{c} is input. Second conductive type second transistor NCH2 includes a drain connected to the source of second conductive type first transistor NCH1, a source connected to ground voltage DVSS and a third gate.

Latch 410 is connected to first node N1 and latches signal V_{N} from first node N1. First node N1 is a connection point between the drain of first conductive type first transistor PCH1 and the drain of second conductive type first transistor NCH1. For example, latch 410 includes a plurality of inverters 412 and 414 connected in series, and the output of the last inverter is input to the input terminal of the first inverter.

Logic operation unit 420 logically operates signal V_{N} from first node N1, which is stored in latch 410, and I/O voltage detection signal P₁ and outputs power-on signal Pₒₙ based on the logically operated result. For example, logic operation unit 420 includes NAND gate 422 and inverter 424. NAND gate 422 logically operates signal V_{N} from first node N1 and I/O voltage detection signal P₁ and outputs the logically operated signal to inverter 424. Inverter 424 inverts the result logically operated by NAND gate 422 and outputs the inverted result.

Power signal controller 430 controls the voltage applied to the gate of second conductive type second transistor NCH2 based on cut signal C₁. For example, power signal controller 430 includes second conductive type first load transistor NCH3 and second conductive type second load transistor NCH4. Second conductive type first load transistor NCH3 includes a source, a gate connected to the source and a drain to which cut signal C₁ is applied. Second conductive type second load transistor NCH4 includes a drain connected to the source of second conductive type first load transistor NCH3 and the gate of second conductive type second transistor NCH2, a source connected to ground voltage DVSS, and a gate connected to the source.

Voltage V_{G} applied to the gate of second conductive type second transistor NCH2 may be expressed by the following Equation 1.

V_{G}=V₁×R_{(NCH4)}/{R_{(NCH3)}+R_{(NCH4)}]

where, V₁ denotes the I/O voltage, R_{(NCH4)} denotes the resistance of the second conductive type second load transistor NCH4, and R_{(NCH3)} denotes the resistance of second conductive type first load transistor NCH3.

Hereinafter, the operation of power-on signal generator 340 illustrated in example FIG. 4 will be described. First, the case where I/O voltage detection signal P₁ having the first level is applied to power-on signal generator 340 will be described.

First conductive type first transistor PCH1 is turned on by I/O voltage detection signal P₁ having the first level (for example, a low level), the level value of signal V_{N} from first node N1 is increased to I/O voltage DVDD, and I/O voltage DVDD is stored in latch 410. Logic operation unit 420 outputs power-on signal Pₒₙ having the first level based on I/O voltage DVDD stored in latch 410 and I/O voltage detection signal P₁ having the first level. Meaning, when I/O voltage detection signal P₁ is at the first level, power-on signal Pₒₙ having the first level is output by logic operation unit 420, regardless of the value stored in latch 410, i.e., core voltage detection signal P_{c}.

Next, the case where I/O voltage detection signal P₁ having the second level (e.g., the high level) is applied to power-on signal generator 340 will be described. First conductive type first transistor PCH1 is turned off by I/O voltage detection signal P₁ having the second level. Since I/O voltage detection signal P₁ is at the second level, the logically operated result of logic operation unit 420 is determined by the value stored in latch 410, and logic operation unit 420 outputs power-on signal Pₒₙ having the second level by I/O voltage DVDD stored in latch 410.

Second conductive type first transistor NCH1 is turned on by core voltage detection signal P_{c} having the second level. Cut signal C₁ is applied to the gate of second conductive type second transistor NCH2 through second conductive type first load transistor NCH3 and second conductive type second load transistor NCH4. The applied voltage is defined in Equation 1.

If the I/O voltage (V₁=DVDD) is stabilized, the voltage input to the gate of second conductive type second transistor NCH2 is increased, second conductive type second transistor NCH2 is turned on, voltage V_{N} of the first node becomes the ground voltage, and latch 410 latches the ground voltage. As a result, logic circuit 420 outputs power-on signal Pₒₙ having the first level.

Example FIG. 5 is a view illustrating a power-on signal output from power-on signal generator 340 illustrated in example FIG. 4.

As illustrated in example to FIG. 5, power-on signal generator 400 in accordance with embodiments can control the power-on circuit by the core voltage having the level less than that of the I/O voltage. If the I/O voltage is stabilized later than core voltage 510, power-on signal Pₒₙ may be forcibly generated so as to generate power-on signal 520.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first Input/Output (I/O) voltage detector configured to detect whether or not an I/O voltage is applied and output an I/O voltage detection signal based on the detected result;
a second I/O voltage detector configured to detect when the applied I/O voltage becomes a reference level value and output a cut signal based on the detected result;
a core voltage detector configured to detect whether or not a core voltage is applied and output a core voltage detection signal based on the detected result; and
a power-on signal generator configured to generate a power-on signal based on the I/O voltage detection signal, the cut signal and the core voltage detection signal and forcibly generate the power-on signal if the I/O voltage is stabilized later than the core voltage.

2. The apparatus of claim 1, wherein the reference level value is a normal state value of the I/O voltage.

3. The apparatus of claim 1, wherein the reference level value is in a range between 80 to 99% of the normal state value.

4. The apparatus of claim 1, wherein the power-on signal generator comprises:
a first conductive type first transistor including a source to which the I/O voltage is applied, a drain, and a first gate to which the I/O voltage detection signal is applied;
a second conductive type first transistor including a drain connected to the drain of the first conductive type first transistor, a source and a second gate to which the cut signal is input;
a second conductive type second transistor including a drain connected to the source of the second conductive type first transistor, a source connected to a ground voltage, and a third gate;
a power signal controller configured to control the voltage applied to the third gate of the second conductive type second transistor based on the cut signal;
a latch connected to a connection node between the drain of the first conductive type first transistor and the drain of the second conductive type first transistor; and
a logic operation unit configured to logically operate a signal stored in the latch and the I/O voltage detection signal and output the power-on signal based on the logically operated result.

5. The apparatus of claim 4, wherein the power signal controller comprises:
a second conductive type first load transistor including a source, a drain to which the cut signal is applied, and a fourth gate connected to the source; and
a second conductive type second load transistor including a drain connected to the source of the second conductive type first load transistor and the gate of the second conductive type second transistor, a source connected to the ground voltage, and a fifth gate connected to the source.

6. The apparatus of claim 4, wherein the logic operation unit comprises:
a NAND gate configured to logically operate a signal stored in the latch and the I/O voltage detection signal and to output the logically operated signal; and
an inverter configured to invert the result logically operated by the NAND gate and to output the inverted result.

7. The apparatus of claim 1, wherein the apparatus comprises a power-on circuit.

8. An apparatus comprising:
a first voltage detector configured to detect whether or not an I/O voltage is applied and output an I/O voltage detection signal based on the detected result;
a second voltage detector configured to detect when the applied I/O voltage becomes a reference level value and output a cut signal based on the detected result;
a third voltage detector configured to detect whether or not a core voltage is applied and output a core voltage detection signal based on the detected result; and
a power signal generator configured to generate a power-on signal which controls an I/O circuit of a semiconductor chip and forcibly generates the power-on signal if the I/O voltage is stabilized later than the core voltage.

9. The apparatus of claim 1, wherein the apparatus comprises a power-on circuit.

10. The apparatus of claim 8, wherein the power-on signal is based on the I/O voltage detection signal, the cut signal and the core voltage detection signal.

11. The apparatus of claim 8, wherein if the I/O voltage is applied and is less than a first reference voltage, the first voltage detector outputs an I/O voltage detection signal having a first voltage level.

12. The apparatus of claim 9, wherein if the I/O voltage is applied and is greater than a first reference voltage, the first voltage detector outputs I/O voltage detection signal having a second voltage level.

13. The apparatus of claim 12, wherein the first voltage level is less than the second voltage level.

14. The apparatus of claim 13, wherein the first voltage level and the second voltage level are determined according to chip driving characteristics.

15. The apparatus of claim 8, wherein if the I/O voltage is applied and is greater than a first reference voltage, the first voltage detector outputs I/O voltage detection signal having a second level.

16. The apparatus of claim 8, wherein if the core voltage is applied and is less than a second reference voltage, the third voltage detector outputs the core voltage detection signal having a first voltage level.

17. The apparatus of claim 16, wherein if the core voltage is applied and is greater than the second reference voltage, the third voltage detector outputs the core voltage detection signal having a second voltage level.

18. The apparatus of claim 8, wherein the power signal generator comprises:
a first transistor having a first conductive type including a source to which the I/O voltage is applied, a drain, and a first gate to which the I/O voltage detection signal is applied;
a second transistor having a second conductive type including a drain connected to the drain of the first transistor, a source and a second gate to which the cut signal is input;
a third transistor having a second conductive type including a drain connected to the source of the second transistor, a source connected to a ground voltage, and a third gate;
a power signal controller configured to control the voltage applied to the third gate of the third transistor based on the cut signal;
a latch connected to a connection node between the drain of the first transistor and the drain of the second transistor; and
a logic operation unit configured to logically operate a signal stored in the latch and the I/O voltage detection signal and output the power-on signal based on the logically operated result.

19. The apparatus of claim 18, wherein the power signal controller comprises:
a first load transistor having a second conductive type including a source, a drain to which the cut signal is applied, and a fourth gate connected to the source; and
a second load transistor having a second conductive type including a drain connected to the source of the first load transistor and the third gate of the third transistor, a source connected to the ground voltage, and a fifth gate connected to the source.

20. The apparatus of claim 18, wherein the logic operation unit comprises:
a NAND gate configured to logically operate a signal stored in the latch and the I/O voltage detection signal and to output the logically operated signal; and
an inverter configured to invert the result logically operated by the NAND gate and to output the inverted result.
